(19) United States
(12) Patent Application Publication
(10) Pub. No.: US 2026/0145928 A1
(43) Pub. Date: May 28, 2026

(54) CAPACITIVE MICROELECTROMECHANICAL PRESSURE TRANSDUCER AND RELATED MANUFACTURING PROCESS

(71) Applicant: STMicroelectronics International N.V., Geneva (CH)

(72) Inventors: Federica CAPRA, Carpaneto Piacentino (PC) (IT); Silvia NICOLI, Briosco (IT); Filippo D'ERCOLI, Milano (IT)

(73) Assignee: STMicroelectronics International N.V., Geneva (CH)

(21) Appl. No.: 19/398,589

(22) Filed: Nov. 24, 2025

(30) Foreign Application Priority Data
Nov. 25, 2024 (IT) 102024000026475

(51) Int. Cl. B81B 3/00; B81C 1/00; G01L 9/00

(52) U.S. Cl. CPC B81B 3/0021; B81C 1/00182; G01L 9/0073; B81B 2201/0264; B81B 2203/0127; B81B 2203/0307; B81B 2203/0315; B81B 2203/0353; B81B 2203/04; B81C 2201/0105; B81C 2201/0132; B81C 2201/016

(57) ABSTRACT

A MEMS pressure transducer includes a semiconductor body, a fixed electrode region, and a membrane suspended above the fixed electrode region to delimit a cavity, the membrane being deformable as a function of pressure. The membrane includes a lower conductive region made of polysilicon which delimits the cavity at the top and is traversed by holes which face the cavity, the lower conductive region being impermeable to gases, except for the holes; an intermediate structure made of polysilicon permeable to gases, which closes the holes. The membrane also includes an upper conductive region made of polysilicon or amorphous silicon, which extends on the intermediate structure and the lower conductive region and is impermeable to gases. The membrane is laterally delimited by a lateral surface, which is formed by the lower conductive region and the upper conductive region. The intermediate structure does not face the lateral surface of the membrane.

### PRIORITY CLAIM

This application claims the priority benefit of Italian Application for Patent No. 102024000026475 filed on Nov. 25, 2024, the content of which is hereby incorporated by reference in its entirety to the maximum extent allowable by law.

### TECHNICAL FIELD

This disclosure relates to an improved capacitive microelectromechanical systems (MEMS) pressure transducer and the related manufacturing process.

### BACKGROUND

As is known, numerous capacitive-type MEMS pressure transducers are currently available, which involve forming a capacitor including an electrode formed by a membrane, which delimits a cavity and deforms at least in part as a function of pressure; in this manner, pressure variations are transduced into capacitance variations, which may be sensed electronically.

For example, United States Patent Application Publication No. 20240391760 (corresponding to European Patent Application No. 24177856.2 and Italian Application No. 102023000010716), incorporated herein by reference, describes a MEMS transducer 1, which is shown in FIG. 1 together with an orthogonal reference system XYZ.

The MEMS transducer 1 comprises a semiconductor body 2, which is delimited at the top by a front surface S2, parallel to the XY plane. A buried cavity 3 extends within the semiconductor body 2, at a distance from the front surface S2. Furthermore, a lower portion of a trench 11 extends through part of the semiconductor body 2, starting from the front surface S2, so as to communicate at the bottom with the buried cavity 3 and laterally delimit a suspended portion 9′ of the semiconductor body 2, which delimits the buried cavity 3 at the top. The suspended portion 9′ of the semiconductor body 2 extends in a cantilever manner, above the buried cavity 3, starting from a fixed portion 9″ of the semiconductor body 2.

The MEMS transducer 1 also comprises a lower dielectric region 4, which extends above the front surface S2, in direct contact with the semiconductor body 2, and is formed for example by thermal oxide. Part of the lower dielectric region 4 covers the fixed portion 9″ of the semiconductor body 2. Furthermore, part of the lower dielectric region 4 extends over the suspended portion 9′ of the semiconductor body 2.

The MEMS transducer 1 also comprises a stopping region 6, which extends above the lower dielectric region 4 and is formed by aluminum oxide (Al₂O₃). Part of the stopping region 6 partially covers the part of the lower dielectric region 4 that covers the fixed portion 9″ of the semiconductor body 2. Furthermore, part of the stopping region 6 extends over the part of the lower dielectric region 4 that overlies the suspended portion 9′ of the semiconductor body 2. The stopping region 6 does not entirely cover the lower dielectric region 4, but leaves a part of the lower dielectric region 4 exposed.

The MEMS transducer 1 further comprises a lower conductive structure 8 made of polysilicon (i.e., polycrystalline silicon material), which comprises a routing region 10, which extends over a portion of the stopping region 6 that overlies, at a distance, the fixed portion 9″ of the semiconductor body 2. The lower conductive structure 8 further comprises a lower electrode region 12, a lower anchoring region 14 and a covering region 16, which are therefore formed by polysilicon, extend over the part of the stopping region 6 that overlies, at a distance, the suspended portion 9′ of the semiconductor body 2 and are coplanar with each other and with the routing region 10. Furthermore, the lower electrode region 12, the lower anchoring region 14 and the covering region 16 are laterally separated from each other. Furthermore, the lower conductive structure 8 comprises a pair of connection regions (not visible in FIG. 1), which connect the lower anchoring region 14 and the covering region 16.

The lower conductive structure 8 also comprises a ground contact region 18, which extends over the part of the lower dielectric region 4 left exposed by the stopping region 6 and is laterally offset with respect to the buried cavity 3. Furthermore, the ground contact region 18 is separated from the routing region 10, the lower electrode region 12, the lower anchoring region 14 and the covering region 16 and extends in part through the lower dielectric region 4, so as to contact, at the bottom, the fixed portion 9″ of the semiconductor body 2.

The lower electrode region 12, the lower anchoring region 14 and the covering region 16 overlie, at a distance, the buried cavity 3. The lower electrode region 12 is partially surrounded by the covering region 16. Furthermore, although not shown here, the lower anchoring region 14 has an elongated shape, approximately a ‘C’ shape (in top view) and laterally surrounds the covering region 16.

Although not shown, the lower conductive structure 8 further comprises a contact region (not shown), which is coplanar with the lower electrode region 12, the lower anchoring region 14, the covering region 16 and the connection regions (not shown) and is interposed between the lower electrode region 12 and the routing region 10, so as to electrically connect them. Furthermore, the lower anchoring region 14, the covering region 16, and the connection regions form a single region that laterally surrounds, at a distance, the lower electrode region 12.

The MEMS transducer 1 further comprises an upper dielectric region 20, which is formed by TEOS oxide and extends above the routing region 10 and the ground contact region 18, as well as above an external portion of the lower anchoring region 14. The upper dielectric region 20 also extends over the part of the lower dielectric region 4 left exposed by the stopping region 6 and over the portions of the stopping region 6 which extend in the space that separates the external portion of the lower anchoring region 14 from the routing region 10. An upper portion of the trench 11 extends through the part of the upper dielectric region 20 which extends over the part of the lower dielectric region 4 left exposed by the stopping region 6 and is laterally offset with respect to the ground contact region 18.

The MEMS transducer 1 further comprises a first, a second and a third upper conductive structure 30, 40, 50, which are formed by polysilicon and have approximately the same shape, in top view (not shown).

The first upper conductive structure 30 has a thickness of, for example, between 200 nm and 500 nm, is formed by polysilicon impermeable to gases and comprises a respective annular region 32, which in top view has an annular shape and extends above portions of the upper dielectric region 20, in direct contact. The annular region 32 of the first upper conductive structure 30 extends above portions of the upper dielectric region 20 that overlie the routing region 10 and above portions of the upper dielectric region 20 that overlie the ground contact region 18. Although not shown, part of the annular region 32 traverses the upper dielectric region 20, so as to contact the ground contact region 18. Furthermore, although not shown, in top view the annular region 32 surrounds the trench 11 and also overlies, at a distance, the fixed portion 9″ of the semiconductor body 2.

The first upper conductive structure 30 further comprises a respective peripheral region 34, which extends above a portion of the upper dielectric region 20 that overlies the routing region 10, outside the annular region 32. Furthermore, the peripheral region 34 also extends through the upper dielectric region 20, so as to contact the underlying routing region 10.

The first upper conductive structure 30 further comprises an internal region 36, hereinafter referred to as the first internal region 36. The first internal region 36 comprises a suspended portion 37′ and an anchoring portion 37″, which form a single monolithic region of polysilicon.

Although not shown, the anchoring portion 37″ has an elongated shape, approximately a ‘C’ shape, in top view. Furthermore, the anchoring portion 37″ is arranged above the lower anchoring region 14, with which it is in direct contact, and laterally delimits a sensing cavity 39. The anchoring portion 37″ has a width (in the XY plane, along the perimeter of the respective elongated shape) smaller than the width of the lower anchoring region 14 and is arranged with respect to the latter so as to leave exposed an internal portion of the lower anchoring region 14, which faces the sensing cavity 39, and also to be laterally offset with respect to the aforementioned external portion of the lower anchoring region 14, which as mentioned is covered by the upper dielectric region 20.

The suspended portion 37′ extends above the anchoring portion 37″, so as to delimit the sensing cavity 39 at the top, which is delimited at the bottom by the internal portion of the lower anchoring region 14, the lower electrode region 12, the covering region 16 and by portions of the stopping region 6 arranged below the suspended portion 37′ and left exposed by the lower electrode region 12, the lower anchoring region 14 and the covering region 16.

The suspended portion 37′ is traversed by a plurality of holes 38 (two visible in FIG. 1) that are through-holes, which face at the bottom the sensing cavity 39. Furthermore, the suspended portion 37′ extends laterally so as to protrude in part outside the anchoring portion 37″. The part of the suspended portion 37′ that protrudes externally with respect to the underlying anchoring portion 37″ overlies a corresponding portion of the upper dielectric region 20, in direct contact.

The suspended portion 37′ is delimited at the bottom by a flat surface S37; furthermore, the suspended portion 37′ forms protection structures SX, which extend from the flat surface S37 in the direction of the lower conductive structure 8.

Although not visible in FIG. 1, the anchoring portion 37″ laterally delimits a lateral opening of the sensing cavity 39, with such lateral opening being delimited at the top by the suspended portion 37′ and facing a corresponding portion of the upper dielectric region 20, which laterally closes this lateral opening, such that the sensing cavity 39 is hermetically closed, with an internal pressure that may for example be between 1 μbar and 1 bar.

The second upper conductive structure 40 has a thickness of, for example, between 100 nm and 300 nm, is formed by polysilicon permeable to gases and comprises a respective annular region 42, which overlies the annular region 32 of the first upper conductive structure 30, in direct contact. In top view, the annular region 42 has approximately the same shape as the annular region 32. The second upper conductive structure 40 also comprises a respective peripheral portion 44, which extends above the peripheral portion 34 of the first upper conductive structure 30; in top view (not shown), the peripheral portion 44 has approximately the same shape as the peripheral portion 34. The second upper conductive structure 40 also comprises a second internal region 46, which is layered and extends over the first internal region 36 and within the holes 38, for example in a conformal manner, therefore without completely filling the holes 38, but coating the respective lateral walls and the respective bottoms. The portions of the second internal region 46 which extend over the bottom of the holes 38 therefore face the sensing cavity 39.

The third upper conductive structure 50 is formed by polysilicon impermeable to gases and comprises a respective annular region 52, which overlies the annular region 42 of the second upper conductive structure 40, in direct contact; in top view (not shown), the annular region 52 has approximately the same shape as the annular region 42. The third upper conductive structure 50 further comprises a respective peripheral portion 54, which extends above the peripheral portion 44 of the second upper conductive structure 40; in top view, the peripheral portion 54 has approximately the same shape as the peripheral portion 44. The third upper conductive structure 50 further comprises a third internal region 56, which extends over the second internal region 46 and comprises portions which extend within the holes 38, so as to fill them. In other words, in each hole 38 a corresponding portion of the third internal region 56 is present, which is coated laterally and at the bottom by a corresponding portion of the second internal region 46.

The first, second and third internal regions 36, 46, 56 have approximately the same shape, in top view. Furthermore, the part of the suspended portion 37′ that overlies the sensing cavity 39 and the overlying portions of the second and the third internal regions 46, 56 form a membrane 55 of polysilicon, which has a thickness for example of between 1 μm and 6 μm, functions as the upper electrode of a sensing capacitor of variable type and faces the underlying lower electrode region 12, which functions as the fixed lower electrode of the sensing capacitor.

In addition, the first, the second and third upper conductive structures 30, 40, 50 are patterned such that the membrane 55 is separated laterally, through an upper trench 59, from the annular regions 32, 42, 52. Furthermore, the peripheral portions 34, 44, 54 are separated from the annular regions 32, 42, 52 by an opening 61, which faces the upper dielectric region 20. A part of the upper trench 59 faces the upper dielectric region 20, while another part of the upper trench 59 faces the underlying upper portion of the trench 11, with which it is in fluidic communication.

The MEMS transducer 1 also comprises a plurality of pads 66 made of conductive material (e.g., aluminum, copper or gold). In FIG. 1, only one pad 66 is visible, which overlies the peripheral portion 54 of the third upper conductive structure 50, in direct contact, so as to be in electrical contact with the routing region 10, and therefore also with the lower electrode region 12. Although not shown, a further pad is electrically connected to the lower anchoring region 14, so as to be set to the same potential as the membrane 55.

The MEMS transducer 1 also comprises a coupling conductive region 68, which is formed for example by metal material (e.g., copper, aluminum or gold), has an annular shape and extends above the annular region 52 of the third upper conductive structure 50, in direct contact. Although not shown, the coupling conductive region 68 may be electrically connected to the ground contact region 18, so as to be set to the same potential as the semiconductor body 2.

The MEMS transducer 1 also comprises a passivation region 69, which is formed, for example, by silicon nitride (SiN) or nitride oxide and extends over the third upper conductive structure 50, in direct contact; a portion of the passivation region 69 laterally coats the membrane 55.

The MEMS transducer 1 also comprises a cap 70 of semiconductor material, which is perforated and is mechanically coupled to the coupling conductive region 68 so as to delimit a chamber, with the membrane 55 extending therein.

In practice, the membrane 55 is free of dielectric regions, therefore it does not include sub-regions with coefficients of thermal expansion different from each other, with a resulting advantage in terms of reduction of unwanted mechanical stresses within the membrane 55. Furthermore, the anchoring portion 37″ allows accurate control of the geometry of the portion of the membrane 55 that is essentially suspended over the sensing cavity 39 and is therefore subject, in use, to deformation.

However, the manufacturing process of the membrane 55 involves an etching operation of a stack of three layers intended to form the first, the second and the third internal region 36, 46, 56, respectively. The layer intended to form the second internal region 46 is formed by polysilicon permeable to gases, while the other two layers are formed by polysilicon impermeable to gases. However, it will be noted that the presence of material discontinuities in the stack of three layers, and in particular the presence of the permeable polysilicon layer, may cause etch discontinuities and therefore may cause non-idealities in the manufacturing process. For example, the impurities present in the permeable polysilicon may cause residues on the landing surface of the etching.

In addition, it will be noted that the presence of peripheral portions of the second internal region 46 that laterally face the upper trench 59, even if only temporarily during the manufacturing process, may result in unwanted variations in pressure within the sensing cavity 39.

There is accordingly a need in the art to provide a capacitive MEMS pressure transducer that overcomes at least in part the drawbacks of the prior art.

### SUMMARY

A MEMS pressure transducer includes a semiconductor body, a fixed electrode region arranged above the semiconductor body, and a membrane which is suspended above the fixed electrode region so as to delimit a cavity. The membrane is deformable as a function of pressure and forms a variable capacitor together with the fixed electrode region. The membrane includes a lower conductive region of polysilicon which delimits an upper boundary of the cavity and is traversed by one or more holes which face the cavity, with the lower conductive region being impermeable to gases except for the one or more holes. The membrane also includes an intermediate structure of polysilicon permeable to gases which closes the one or more holes, and an upper conductive region of polysilicon or amorphous silicon which extends on the intermediate structure and on the lower conductive region, with the upper conductive region being impermeable to gases. The membrane is laterally delimited by a lateral surface which is formed by the lower conductive region and by the upper conductive region, and the intermediate structure does not face the lateral surface of the membrane.

Optionally, a minimum distance between the intermediate structure and the lateral surface is at least equal to 1 micrometer.

Optionally, the minimum distance between the intermediate structure and the lateral surface is at least equal to 10 micrometers.

Optionally, the intermediate structure includes a single intermediate region of polysilicon permeable to gases which extends on a part of the lower conductive region and within the one or more holes.

Optionally, the intermediate structure includes a plurality of intermediate regions of polysilicon permeable to gases separated from each other, with each intermediate region extending in a corresponding hole.

Optionally, the transducer further includes a lower anchoring region of conductive material, with the lower anchoring region and the fixed electrode region being coplanar and laterally separated. The lower conductive region may form a portion of the membrane and an upper anchoring region which laterally delimits the cavity and extends to contact, at its bottom surface, the lower anchoring region.

Optionally, the membrane has a thickness of between 1 micrometer and 6 micrometers.

Optionally, the lower conductive region has a thickness of between 200 nanometers and 1.5 micrometers.

Optionally, the cavity is hermetically closed and has an internal pressure of between 1 microbar and 1 bar.

Optionally, the transducer further includes a stopping region of aluminum oxide extending above the semiconductor body, with the fixed electrode region extending over the stopping region.

Optionally, the membrane has a shape selected from cylindrical, polygonal, parallelepiped, and polygonal-based prism configurations.

Optionally, the transducer further includes a passivation region of silicon nitride or nitride oxide extending over the upper conductive region.

Optionally, the transducer further includes a perforated cap mechanically coupled to the membrane so as to delimit a chamber with the membrane extending therein.

A process for manufacturing a MEMS pressure transducer includes forming a semiconductor body, forming a fixed electrode region arranged above the semiconductor body, and forming a membrane which is suspended above the fixed electrode region so as to delimit a cavity. The membrane is deformable as a function of pressure and forms a variable capacitor together with the fixed electrode region. Forming the membrane includes forming a lower conductive region of polysilicon which delimits an upper boundary of the cavity and is traversed by one or more holes which face the cavity, with the lower conductive region being impermeable to gases except for the one or more holes. The process also includes forming an intermediate structure of polysilicon permeable to gases which closes the one or more holes, and forming an upper conductive region of polysilicon or amorphous silicon which extends on the intermediate structure and the lower conductive region, with the upper conductive region being impermeable to gases. The manufacturing process results in the membrane being laterally delimited by a lateral surface which is formed by the lower conductive region and the upper conductive region, and the intermediate structure does not face the lateral surface of the membrane.

Optionally, the process further includes forming a front dielectric layer above the fixed electrode region, forming a first conductive layer which is formed by polysilicon impermeable to gases and extends on the front dielectric layer and through the front dielectric layer so as to laterally delimit a sacrificial portion of the front dielectric layer. The first conductive layer is further traversed by the one or more holes which traverse a portion of the first conductive layer that overlies the sacrificial portion. The process may also include forming a second conductive layer on the first conductive layer, with the second conductive layer being formed by polysilicon permeable to gases and extending within the one or more holes, and selectively removing portions of the second conductive layer so that residual portions of the second conductive layer form the intermediate structure which includes portions which face the sacrificial portion. The process may further include removing the sacrificial portion by flowing a gaseous chemical agent through the portions of the intermediate structure that face the sacrificial portion, forming a third conductive layer on the intermediate structure and the first conductive layer, with the third conductive layer being formed by polysilicon or amorphous silicon and being impermeable to gases, and with a same etching, selectively removing portions of the first and third conductive layers such that the residual portions of the first and third conductive layers form the lower conductive region and the upper conductive region of the membrane, respectively.

Optionally, forming the third conductive layer includes performing epitaxial growth of polysilicon at ambient pressure.

Optionally, the process further includes performing a thermal treatment in a nitrogen environment to set a pressure value in the cavity.

Optionally, the second conductive layer conformally coats lateral walls and bottoms of the one or more holes without completely filling the holes.

Optionally, selectively removing portions of the second conductive layer includes performing a masked etching before removing the sacrificial portion.

Optionally, selectively removing portions of the second conductive layer includes performing a thermal treatment to oxidize portions of the second conductive layer and successively removing the oxidized portions of the second conductive layer during the removal of the sacrificial portion.

Optionally, the intermediate structure includes a single intermediate region of polysilicon permeable to gases which extends on a part of the lower conductive region and within the one or more holes.

Optionally, the intermediate structure includes a plurality of intermediate regions of polysilicon permeable to gases separated from each other, with each intermediate region extending in a corresponding hole.

### BRIEF DESCRIPTION OF THE DRAWINGS

For a better understanding of the present invention, embodiments thereof are now described, purely by way of non-limiting example, with reference to the attached drawings, wherein:

FIG. 1 schematically shows a cross-section of a MEMS transducer;

FIGS. 2 and 3 schematically show cross-sections of variants of the present MEMS transducer;

FIGS. 4-9 schematically show cross-sections of the MEMS transducer shown in FIG. 2, during successive steps of a manufacturing process;

FIGS. 10-14 schematically show cross-sections of the MEMS transducer shown in FIG. 3, during successive steps of a manufacturing process;

FIG. 15 schematically shows a cross-section of the MEMS transducer shown in FIG. 2, during a step of a variant of the manufacturing process; and

FIG. 16 schematically shows a cross-section of the MEMS transducer shown in FIG. 3, during a step of a variant of the manufacturing process.

### DETAILED DESCRIPTION

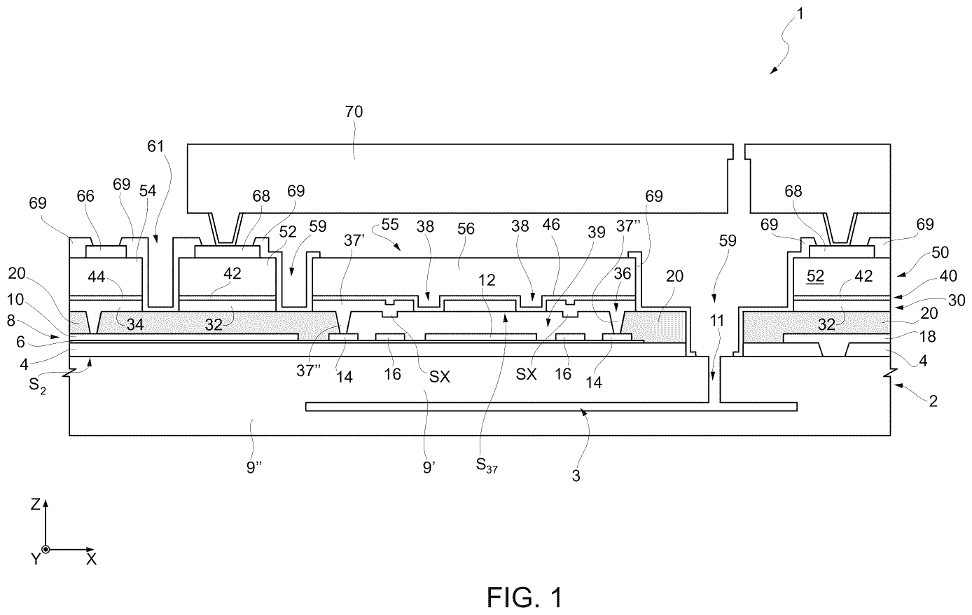

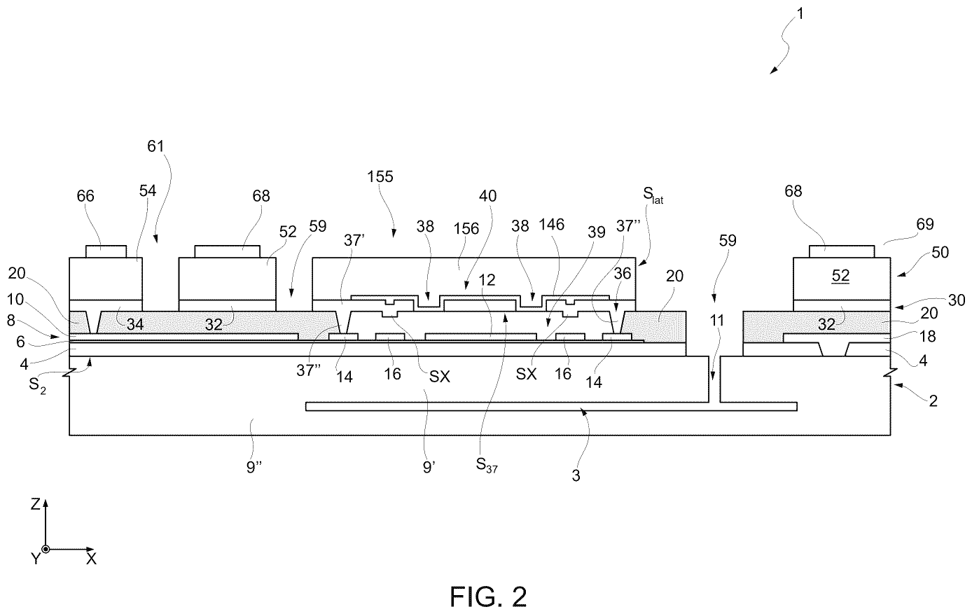

FIG. 2 shows a first embodiment of a MEMS transducer 100, which is now described with reference to the differences with respect to the MEMS transducer 1 shown in FIG. 1. Elements already present in the MEMS transducer 1 are indicated with the same reference signs, unless otherwise specified. For simplicity of representation, the cap 70, though optional, is not shown. Furthermore, although not further explained, variations with respect to the thicknesses mentioned with reference to FIG. 1 are possible.

In detail, the annular region 42 and the peripheral portion 44 of the second upper conductive structure 40 are absent. Consequently, the annular region 52 and the peripheral portion 54 of the third upper conductive structure 50 directly contact, respectively, the annular region 32 and the peripheral portion 34 of the first upper conductive structure 30.

The membrane, here indicated as 155, is laterally delimited by a lateral surface Slat, which faces the upper trench 59. Purely by way of example, the membrane 155 may have an approximately cylindrical shape or may have a polygonal shape in top view, therefore it may have, for example, the shape of a parallelepiped or a polygonal-based prism; the shape of the lateral surface Slat varies accordingly.

The second internal region, here indicated as 146, is still formed by polysilicon permeable to gases, is layered and still extends over the first internal region 36 and within the holes 38, for example in a conformal manner, therefore without completely filling the holes 38, but coating the respective lateral walls and the respective bottoms. The portions of the second internal region 146 which extend over the bottom of the holes 38 face the sensing cavity 39.

In greater detail, the second internal region 146 does not laterally face the lateral surface Slat of the membrane 155. In other words, the second internal region 146 extends at a distance from the lateral surface Slat of the membrane 155.

In even greater detail, the second internal region 146 is covered by, in direct contact, a central portion of the third internal region, here indicated as 156. Furthermore, a perimeter portion of the third internal region 156 laterally surrounds the second internal region 146; this perimeter portion of the third internal region 156 overlies, in direct contact, a perimeter portion of the suspended portion 37′ of the first internal region 36, which, without any loss of generality, protrudes laterally with respect to the underlying anchoring portion 37″.

In practice, the perimeter portions of the suspended portion 37′ of the first internal region 36 and of the third internal region 156 form the lateral wall of the membrane 155 and therefore define the lateral surface Slat, which, without any loss of generality, protrudes laterally with respect to the underlying anchoring portion 37″. Furthermore, the first and the third internal regions 36, 156 form a body of polysilicon impermeable to gases; the second internal region 146 is a monolithic region of polysilicon permeable to gases, which is encapsulated in such a body of polysilicon impermeable to gases, except for the portions of the second internal region 146 that extend over the bottom of the holes 38 and face the sensing cavity 39.

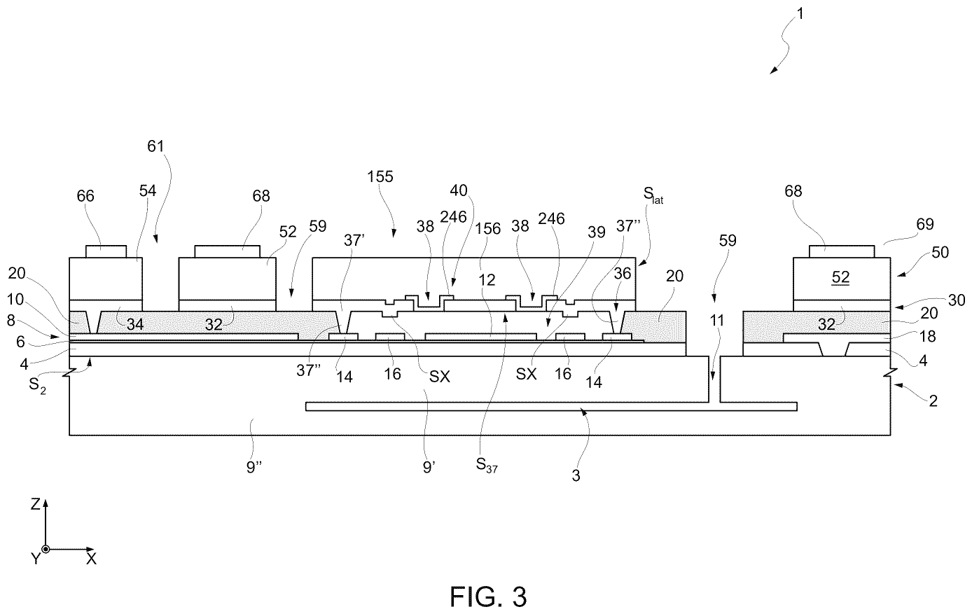

According to a variant shown in FIG. 3, instead of the second internal region 146, a plurality of second internal regions 246 (two shown in FIG. 3) are present, which are again formed by polysilicon permeable to gases and are spaced from each other. Each second internal region 246 is layer-shaped and coats the lateral wall and the bottom of a corresponding hole 38, for example in a conformal manner. Without any loss of generality, an upper portion of each second internal region 246 coats at the top a part of the suspended portion 37′ that surrounds the corresponding hole 38. The portions of the second internal regions 246 that extend over the bottom of the holes 38 therefore face the sensing cavity 39.

In practice, both in the variant shown in FIG. 2 and in the variant shown in FIG. 3, permeable polysilicon regions that face the lateral surface Slat are not present. Both the second internal region 146 and the second internal regions 246 form an intermediate structure of permeable polysilicon, which closes the holes 38 and is encapsulated within the impermeable body formed by the underlying first internal region 36 and the overlying third internal region 156, except for the portions that face the sensing cavity 39. This prevents gas exchanges between the sensing cavity 39 and the outside world, without the need to further seal the sensing cavity 39, for example by using a further layer of nitride; however, this latter action would still require time to be carried out, during which the sealing of the sensing cavity 39 would not be optimal.

Again with reference to the prevention of gas exchanges between the sensing cavity 39 and the outside world, in order to reduce unwanted fluidic coupling between the sensing cavity 39 and the outside world, referring to the variant shown in FIG. 2, the minimum distance between the lateral surface Slat and the second internal region 146 (defined as the minimum distance present between any point of the second internal region 146 and any point of the lateral surface Slat) may be at least equal to 1 μm. Furthermore, the variant shown in FIG. 3 allows the permeable polysilicon to be further spaced from the lateral surface Slat; in this regard, the minimum distance between the lateral surface Slat and the second internal region 246 closest to the lateral surface Slat (defined as the minimum distance present between any point of the second internal region 246 closest to the lateral surface Slat and any point of the lateral surface Slat) may for example be at least equal to 10 μm.

Furthermore, as subsequently clarified, further advantages arise in the manufacturing processes of both variants, which are described below.

In detail, the variant shown in FIG. 2 may be manufactured starting from a semiconductor wafer 99 comprising the semiconductor body 2, in the following manner.

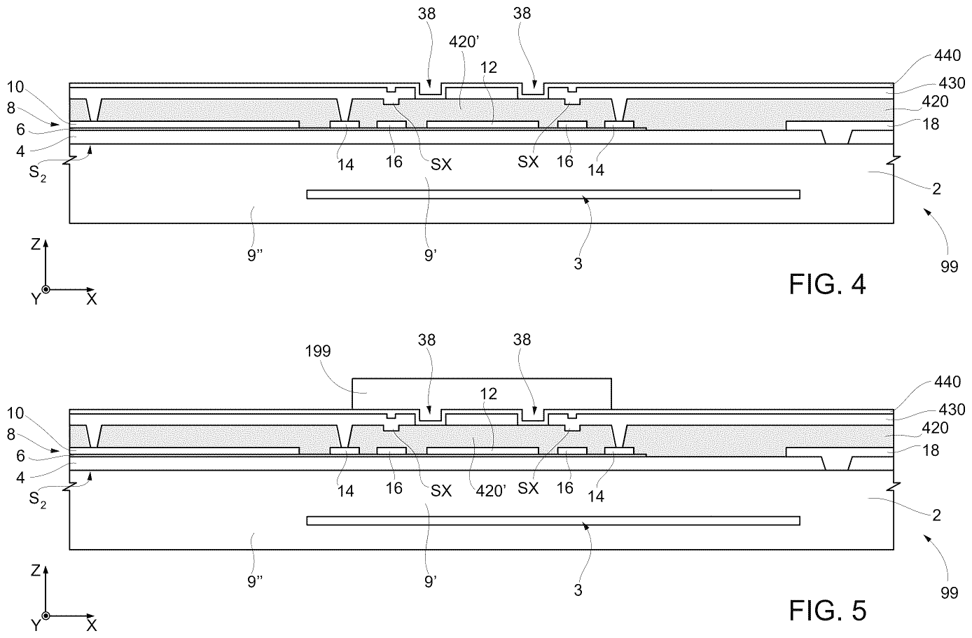

Initially, as shown in FIG. 4, the buried cavity 3, the lower dielectric region 4, the stopping region 6, the ground contact region 18 and the lower conductive structure 8, which comprises the routing region 10, the lower electrode region 12, the lower anchoring region 14 and the covering region 16, are formed in a known manner.

Furthermore, a front dielectric layer 420 is formed, which is intended to form the upper dielectric region 20 and is formed for example of TEOS oxide.

Furthermore, a first conductive layer 430 of polysilicon impermeable to gases is formed over the front dielectric layer 420, which has a thickness of, for example, between 0.2 μm and 1.5 μm and includes portions which extend through the front dielectric layer 420 to contact the routing region 10 and the lower anchoring region 14. In this regard, hereinafter reference is made to a sacrificial region 420′ to indicate the portion of the front dielectric layer 420 that is laterally delimited by the portion of the first conductive layer 430 which extends through the front dielectric layer 420 to contact the lower anchoring region 14 and is intended to form the anchoring portion 37″ of the first internal region 36. A portion of the first conductive layer 430 extends above the sacrificial region 420′, which is intended to form the suspended portion 37′ of the first internal region 36. In addition, the sacrificial region 420′ overlies the lower electrode region 12, the covering region 16 and the internal portion of the lower anchoring region 14.

As shown again in FIG. 4, the first conductive layer 430 is traversed by the holes 38, which face the sacrificial region 420′. Furthermore, a second conductive layer 440 of polysilicon permeable to gases, with a thickness for example of between 100 nm and 300 nm, is present over the first conductive layer 430. Without any loss of generality, the second conductive layer 440 coats the lateral walls and the bottom of the holes 38 in a conformal manner, i.e., without filling them. The portions of the sacrificial region 420′ which form the bottoms of the holes 38 are then coated by corresponding portions of the second conductive layer 440, in direct contact.

Subsequently, as shown in FIG. 5, a masking region 199 made of oxide is formed (but variants are possible wherein the masking region 199 is formed of resist or a combination of oxide and resist), which overlies a portion of the second conductive layer 440, which in turn overlies, at a distance, the sacrificial region 420′ and is intended to form the second internal region 146. The masking region 199 leaves exposed portions of the second conductive layer 440 that are laterally offset with respect to the underlying sacrificial region 420′; the exposed portions of the second conductive layer 440 overlie, inter alia, the portion of the first conductive layer 430 that extends through the front dielectric layer 420 to contact the lower anchoring region 14 and is intended to form the anchoring portion 37″ of the first internal region 36.

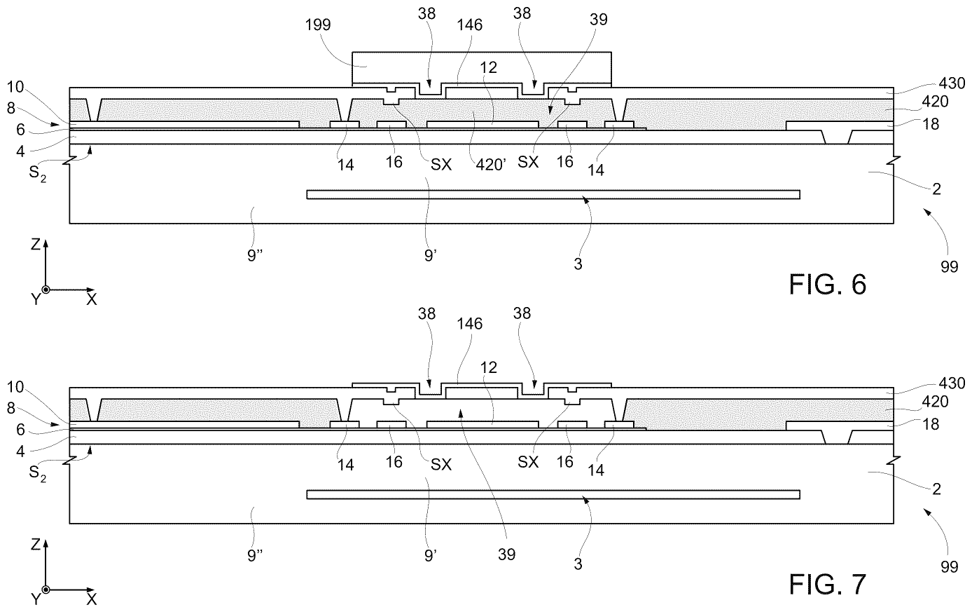

Subsequently, as shown in FIG. 6, the exposed portions of the second conductive layer 440 are selectively removed, such that the residual portion of the second conductive layer 440 forms the second internal region 146. To this end, a “dry” etching is for example performed, wherein the masking region 199 functions as a “hard mask”.

The selective removal of the exposed portions of the second conductive layer 440 results in the exposure of underlying portions of the first conductive layer 430.

Subsequently, as shown in FIG. 7, the masking region 199 is removed by means of etching with gaseous hydrofluoric acid (HF), which is also flowed through the holes 38, thus through the portions of the second internal region 146 that coat the bottoms of the holes 38. In this manner, the sacrificial region 420′ is also removed; the sensing cavity 39 is thus formed. If the masking region 199 is formed in whole or in part of resist, the etching with gaseous hydrofluoric acid is preceded by a “dry” etching to remove the resist from the masking region 199.

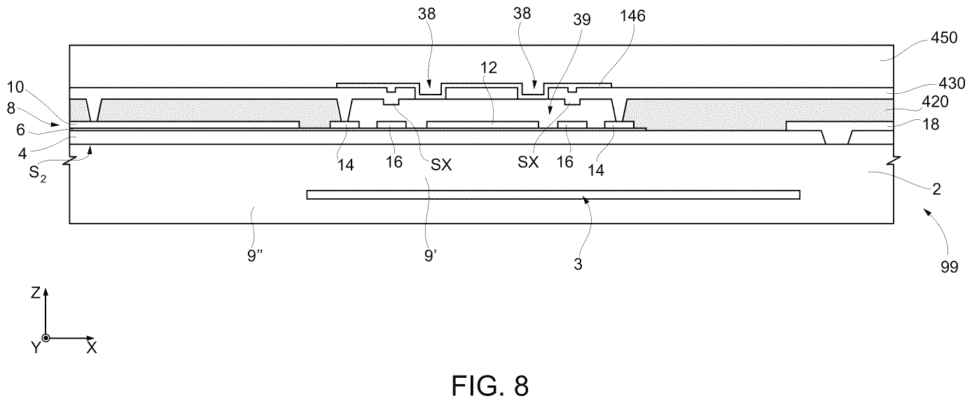

Subsequently, as shown in FIG. 8, a third conductive layer 450 made of polysilicon impermeable to gases is formed over the exposed portions of the first conductive layer 430 and over the second internal region 146. The third conductive layer 450 fills the holes 38, so as to close them hermetically, i.e., to prevent the gas from flowing through the holes 38. Furthermore, the third conductive layer 450 surrounds at the top and laterally the second internal region 146.

In particular, in order to prevent polysilicon from penetrating the sensing cavity 39, creating unwanted contacts with the lower electrode region 12, the third conductive layer 450 may be formed by performing an epitaxial growth of polysilicon (e.g., at ambient pressure).

Subsequently, although not shown, a thermal treatment in a nitrogen environment may be performed, to create vacuum in the sensing cavity 39 or in any case to set the pressure value in the sensing cavity 39.

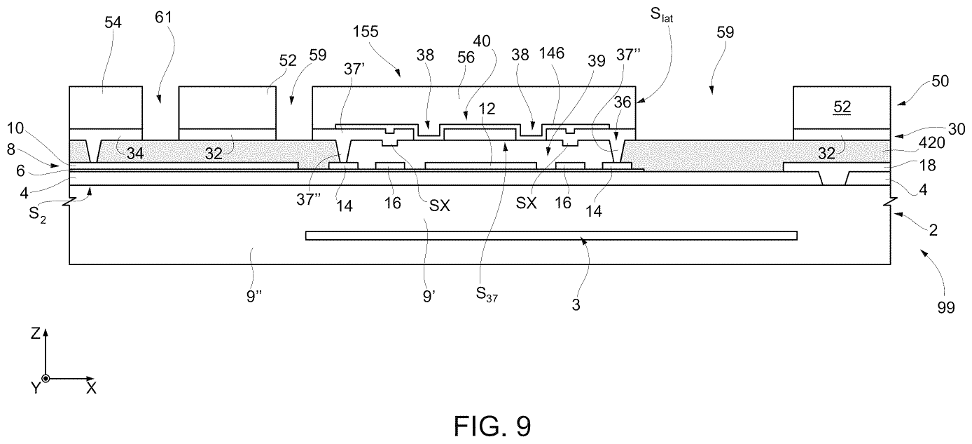

Subsequently, as shown in FIG. 9, portions of the first and the third conductive layers 430, 450 are selectively removed, for example by performing a “dry” etching, such that the remaining portions of the first and the third conductive layers 430, 450 form the first and the third upper conductive structures 30, 50, respectively. In particular, the upper trench 59 and the opening 61 are formed, therefore the membrane 155 is also defined.

In greater detail, the selective removal of portions of the third conductive layer 450 and underlying portions of the first conductive layer 430 occurs with the same etching, without involving the removal of permeable polysilicon, by virtue of the preceding patterning of the second conductive layer 440. The etching therefore involves regions formed by the same material, therefore without encountering material discontinuities, with resulting advantages in terms of reduction of manufacturing non-idealities.

Subsequently, although not shown, the manufacturing process may proceed in a manner known per se, so as to form, inter alia, the pads 66 and the trench 11, as well as to couple the cap 70.

The variant of the MEMS transducer 100 shown in FIG. 3 may be manufactured following the manufacturing process described below with reference, for brevity, only to the differences with respect to the manufacturing process described with reference to FIGS. 4-9.

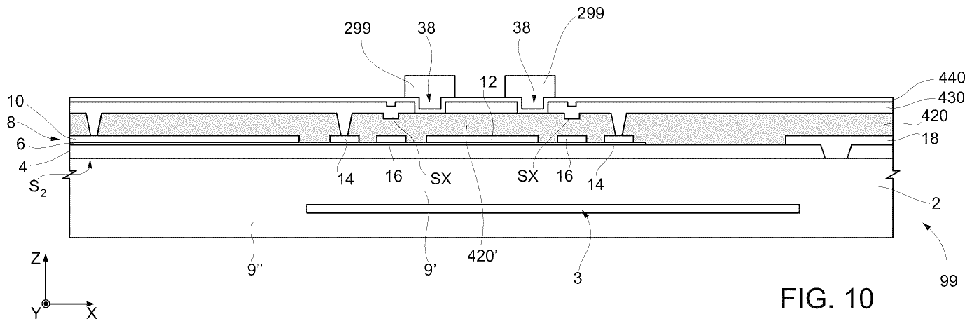

Instead of the masking region 199, a plurality of masking regions 299 made of oxide are formed (with variants also possible wherein the masking regions 299 are made of resist or a combination of resist and oxide), as shown in FIG. 10. Each masking region 299 overlies a corresponding portion of the second conductive layer 440 that extends in a corresponding hole 38.

The masking regions 299 are separated from each other and leave exposed, as well as portions of the second conductive layer 440 that are laterally offset with respect to the underlying sacrificial region 420′, also portions of the second conductive layer 440 that overlie, at a distance, the underlying sacrificial region 420′.

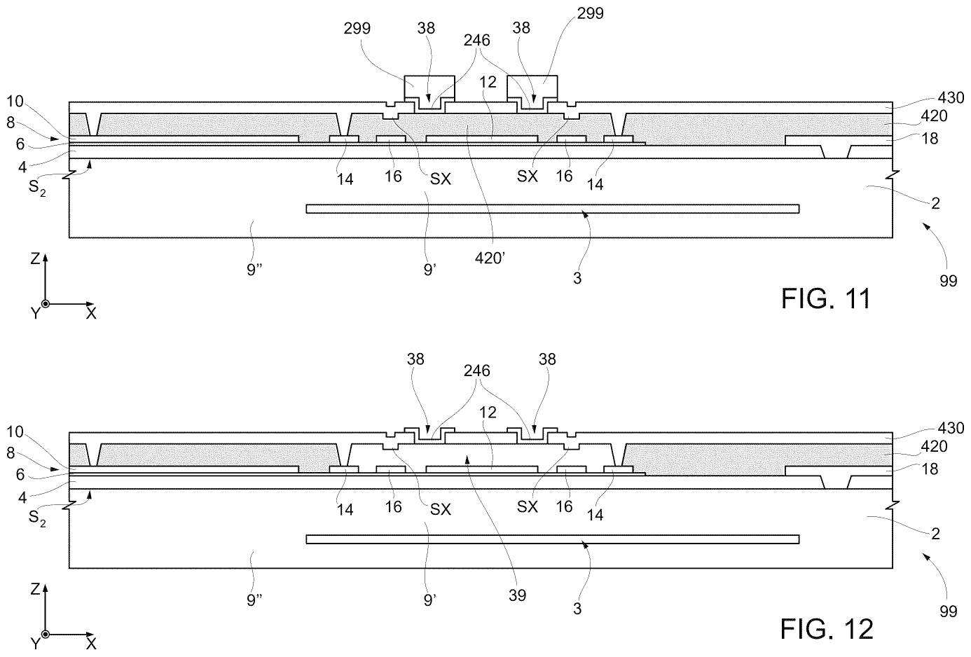

Subsequently, as shown in FIG. 11, the exposed portions of the second conductive layer 440 are selectively removed, such that the residual portions of the second conductive layer 440 form the second internal regions 246. To this end, for example a “dry” etching is performed, wherein the masking regions 299 function as a mask.

The selective removal of the exposed portions of the second conductive layer 440 results in the exposure of underlying portions of the first conductive layer 430.

Subsequently, as shown in FIG. 12, the masking regions 299 are removed by means of etching with gaseous hydrofluoric acid (HF), which is also flowed through the holes 38, thus through the portions of the second internal regions 246 that coat the bottoms of the holes 38. In this manner, the sacrificial region 420′ is also removed; the sensing cavity 39 is thus formed. If the masking regions 299 are formed in whole or in part of resist, the etching with gaseous hydrofluoric acid is preceded by a “dry” etching to remove the resist from the masking regions 299.

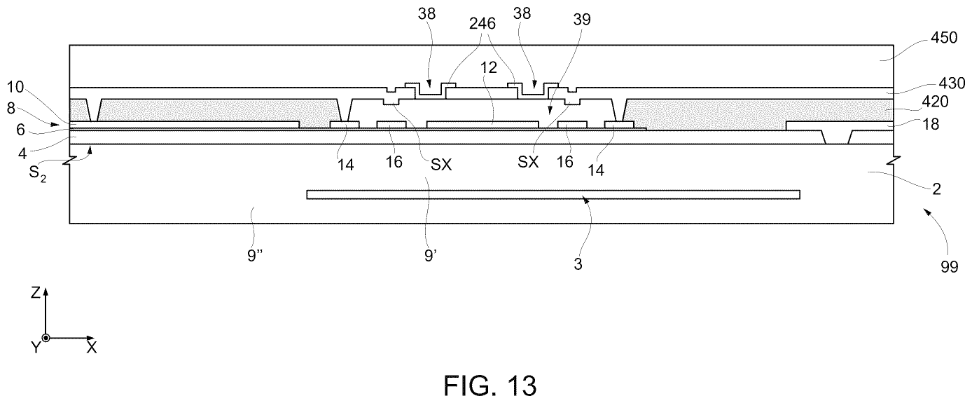

Subsequently, as shown in FIG. 13, the third conductive layer 450 made of polysilicon impermeable to gases is formed over the exposed portions of the first conductive layer 430 and above the second internal regions 246. The third conductive layer 450 fills the holes 38, so as to close them hermetically, i.e., so as to prevent the gas from flowing through the holes 38. Furthermore, the third conductive layer 450 surrounds at the top and laterally each second internal region 246.

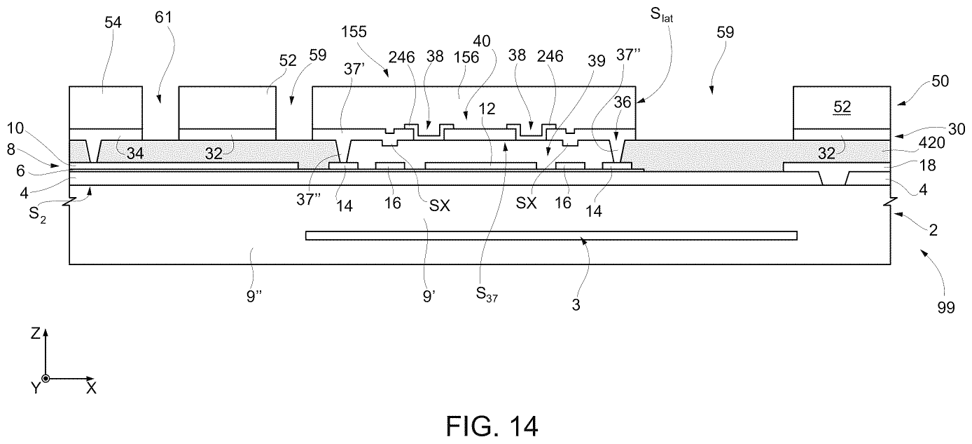

Subsequently, as shown in FIG. 14, portions of the first and the third conductive layers 430, 450 are selectively removed, for example by performing a “dry” etching, such that the remaining portions of the first and the third conductive layers 430, 450 form the first and the third upper conductive structures 30, 50, respectively. In particular, the upper trench 59 and the opening 61 are formed, therefore the membrane 155 is also formed. Also in this case, the selective removal of portions of the third conductive layer 450 and of underlying portions of the first conductive layer 430 occurs with the same etching, without involving the removal of permeable polysilicon, by virtue of the preceding patterning of the second conductive layer 440. The etching therefore involves regions formed by the same material, without encountering material discontinuities.

Subsequently, the manufacturing process may proceed in a manner known per se and therefore not shown.

Variants are also possible wherein, both for the variant shown in FIG. 2 and for the variant shown in FIG. 3, the patterning of the second conductive layer 440 is carried out differently from what has been described.

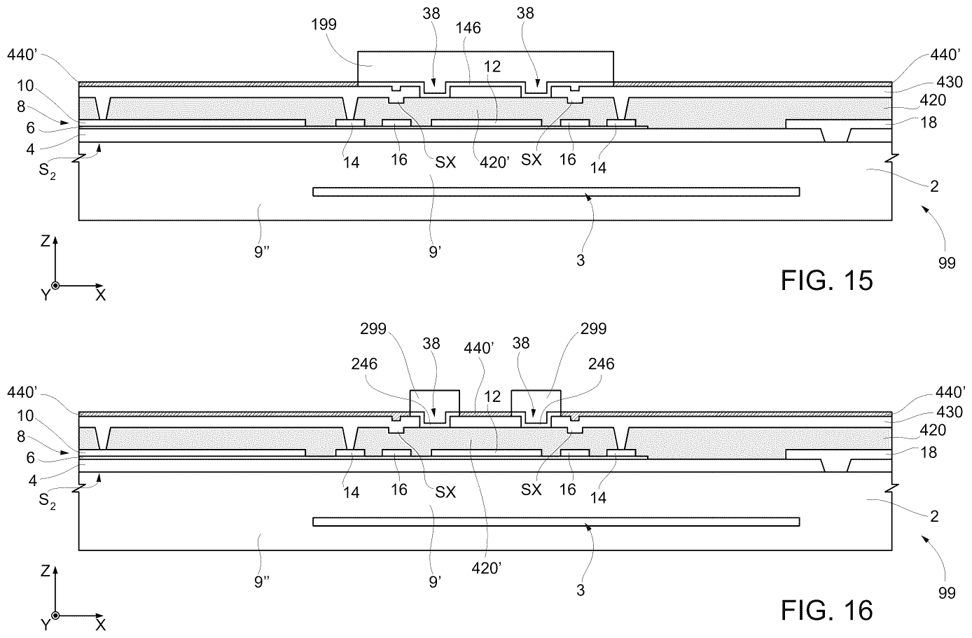

For example, with reference to the manufacturing process of the variant shown in FIG. 2 of the MEMS transducer 100, following the formation of the masking region 199 of TEOS oxide, a thermal treatment may be performed that causes the oxidation of the exposed portions of the second conductive layer 440, as shown in FIG. 15, wherein the oxidized portions of the second conductive layer 440 are indicated by 440′, and wherein the portion of the second conductive layer 440 protected by the masking region 199 is already indicated as 146, as it coincides with the second internal region 146.

Subsequently, although not described again, the operations described with reference to FIG. 7 are performed. The masking region 199 of TEOS oxide, the sacrificial region 420′ and the oxidized portions 440′ of the second conductive layer 440 are then removed, by using gaseous hydrofluoric acid, so as to obtain again what has been shown in FIG. 7. The manufacturing process may then proceed in the same manner as previously described.

With reference to the manufacturing process of the variant shown in FIG. 3 of the MEMS transducer 100, following the formation of the masking regions 299, a thermal treatment may be performed instead so as to oxidize the portions of the second conductive layer 440 left exposed by the masking regions 299, as shown in FIG. 16, wherein the oxidized portions of the second conductive layer 440 are still indicated by 440′, and wherein the portions of the second conductive layer 440 protected by the masking regions 299 are already indicated as 246, as they coincide with the second internal regions 246.

Subsequently, although not described again, the operations described with reference to FIG. 12 are performed. The masking regions 299 of TEOS oxide, the sacrificial region 420′ and the oxidized portions 440′ of the second conductive layer 440 are then removed by using gaseous hydrofluoric acid, so as to obtain again what has been shown in FIG. 12. The manufacturing process may then proceed in the same manner as previously described.

The advantages that the present solution affords are clear from the preceding description.

In particular, the patterning of the permeable polysilicon allows avoidance of encountering material discontinuities during the etching of the first and the third conductive layers 430, 450. In this manner, the possibility of introducing impurities in the permeable polysilicon, which might cause non-idealities in the manufacturing process, is reduced and the sealing of the sensing cavity 39 is improved, since the second internal region 146 (or the second internal regions 246) do not face the lateral surface Slat of the membrane 155, but only the sensing cavity 39, therefore they cannot form unwanted fluidic channels between the sensing cavity 39 and the outside world.

Furthermore, the variant shown in FIG. 2 is characterized by a single region made of permeable polysilicon, with a resulting advantage in terms of reduction of the roughness of the membrane 155. The variant shown in FIG. 3 instead allows the permeable polysilicon to be spaced farther from the lateral surface Slat and the overall volume occupied by the permeable polysilicon, which represents the material at greatest risk of non-ideality within the membrane 155, to be reduced.

Finally, it is clear that modifications and variations may be made to the MEMS transducer and to the related manufacturing process previously described and illustrated, without departing from the scope of the present invention, as defined in the attached claims.

For example, variants are possible in which the membrane 155 has a different shape, such as for example the shape of a polygonal-based prism, in which case the membrane 155 is laterally delimited by a plurality of lateral walls, which define the lateral surface Slat.

The buried cavity 3 may be absent.

The third conductive layer 450, and therefore also the third internal region 156 of the membrane 155, may be formed of amorphous silicon, rather than polysilicon.

The front dielectric layer 420, and therefore also the upper dielectric region 20, may be formed of dielectric material other than TEOS oxide.

Furthermore, the polysilicon permeable to gases may completely fill each hole 38, rather than conformally coating the bottom and the lateral wall, in which case the shapes of the second internal region 146 (or the second internal regions 246), the third internal region 156, the second conductive layer 440, and the third conductive layer 450 are modified accordingly.

1. A MEMS pressure transducer, comprising:
a semiconductor body;
a fixed electrode region arranged above the semiconductor body; and
a membrane suspended above the fixed electrode region to delimit a cavity, the membrane being deformable as a function of pressure and forming a variable capacitor together with the fixed electrode region;
wherein the membrane comprises:
a lower conductive region made of polysilicon which delimits an upper boundary of the cavity and is traversed by one or more holes which face the cavity, the lower conductive region being impermeable to gases, except for the one or more holes;
an intermediate structure made of polysilicon permeable to gases which closes said one or more holes; and
an upper conductive region made of polysilicon or amorphous silicon which extends on the intermediate structure and on the lower conductive region, said upper conductive region being impermeable to gases;
wherein the membrane is laterally delimited by a lateral surface formed by the lower conductive region and by the upper conductive region; and
wherein the intermediate structure does not face the lateral surface of the membrane.

2. The MEMS pressure transducer according to claim 1, wherein a minimum distance between the intermediate structure and the lateral surface is at least equal to 1 μm.

3. The MEMS pressure transducer according to claim 2, wherein a minimum distance between the intermediate structure and the lateral surface is at least equal to 10 μm.

4. The MEMS pressure transducer according to claim 1, wherein the intermediate structure comprises a single intermediate region made of polysilicon permeable to gases and which extends on a part of the lower conductive region and within the one or more holes.

5. The MEMS pressure transducer according to claim 1, wherein the intermediate structure comprises a plurality of intermediate regions made of polysilicon permeable to gases separated from each other, each intermediate region extending in a corresponding hole.

6. The MEMS pressure transducer according to claim 1, further comprising:
a lower anchoring region of conductive material, the lower anchoring region and the fixed electrode region being coplanar and laterally separated; and
wherein the lower conductive region forms a portion of the membrane and an upper anchoring region, which laterally delimits the cavity and extends to contact, at its bottom surface, the lower anchoring region.

7. The MEMS pressure transducer according to claim 1, wherein the membrane has a thickness of between 1 μm and 6 μm.

8. The MEMS pressure transducer according to claim 1, wherein the lower conductive region has a thickness of between 200 nm and 1.5 μm.

9. The MEMS pressure transducer according to claim 1, wherein the cavity is hermetically closed and has an internal pressure of between 1 μbar and 1 bar.

10. The MEMS pressure transducer according to claim 1, further comprising a stopping region made of aluminum oxide extending above the semiconductor body, wherein the fixed electrode region extends over the stopping region.

11. The MEMS pressure transducer according to claim 1, wherein the membrane has a shape selected from the group consisting of: cylindrical, polygonal, parallelepiped, and polygonal-based prism.

12. The MEMS pressure transducer according to claim 1, further comprising a passivation region made of silicon nitride or nitride oxide extending over the upper conductive region.

13. The MEMS pressure transducer according to claim 1, further comprising a perforated cap mechanically coupled to the membrane to delimit a chamber with the membrane extending therein.

14. A process for manufacturing a MEMS pressure transducer, comprising:
forming a semiconductor body;
forming a fixed electrode region arranged above the semiconductor body; and
forming a membrane suspended above the fixed electrode region to delimit a cavity, the membrane being deformable as a function of pressure and forming a variable capacitor together with the fixed electrode region; and
wherein forming the membrane comprises:
forming a lower conductive region made of polysilicon which delimits an upper boundary of the cavity and is traversed by one or more holes which face the cavity, the lower conductive region being impermeable to gases, except for the one or more holes;
forming an intermediate structure made of polysilicon permeable to gases which closes said one or more holes; and
forming an upper conductive region made of polysilicon or amorphous silicon which extends on the intermediate structure and the lower conductive region, said upper conductive region being impermeable to gases;
wherein the membrane is laterally delimited by a lateral surface formed by the lower conductive region and the upper conductive region; and
wherein the intermediate structure does not face the lateral surface of the membrane.

15. The process according to claim 14, further comprising:
forming a front dielectric layer above the fixed electrode region;
forming a first conductive layer made of polysilicon impermeable to gases and which extends on the front dielectric layer and through the front dielectric layer to laterally delimit a sacrificial portion of the front dielectric layer, said first conductive layer being further traversed by said one or more holes which traverse a portion of the first conductive layer that overlies the sacrificial portion;
forming a second conductive layer on the first conductive layer, said second conductive layer made of polysilicon permeable to gases and extending within the one or more holes; and
selectively removing portions of the second conductive layer so that residual portions of the second conductive layer form the intermediate structure, and which comprises portions which face the sacrificial portion;
removing the sacrificial portion by flowing a gaseous chemical agent through the portions of the intermediate structure that face the sacrificial portion;
on the intermediate structure and the first conductive layer, forming a third conductive layer made of polysilicon or amorphous silicon and is impermeable to gases; and
with a same etching, selectively removing portions of the first and third conductive layers such that the residual portions of the first and third conductive layers form the lower conductive region and the upper conductive region of the membrane, respectively.

16. The process according to claim 15, wherein forming the third conductive layer comprises performing epitaxial growth of polysilicon at ambient pressure.

17. The process according to claim 15, further comprising performing a thermal treatment in a nitrogen environment to set a pressure value in the cavity.

18. The process according to claim 15, wherein the second conductive layer conformally coats lateral walls and bottoms of the one or more holes without completely filling the holes.

19. The process according to claim 15, wherein selectively removing portions of the second conductive layer comprises performing a masked etching, before removing the sacrificial portion.

20. The process according to claim 15, wherein selectively removing portions of the second conductive layer comprises performing a thermal treatment to oxidize portions of the second conductive layer and successively removing the oxidized portions of the second conductive layer during the removal of the sacrificial portion.

21. The process according to claim 14, wherein the intermediate structure comprises a single intermediate region made of polysilicon permeable to gases, which extends on a part of the lower conductive region and within the one or more holes.

22. The process according to claim 14, wherein the intermediate structure comprises a plurality of intermediate regions made of polysilicon permeable to gases separated from each other, each intermediate region extending in a corresponding hole.
